(19) United States
(12) Patent Application Publication
(10) Pub. No.: US 2026/0277364 A1
(43) Pub. Date: Sep. 17, 2026

(54) DISPLAY DEVICE

(71) Applicant: LG Display Co., Ltd., Seoul (KR)

(72) Inventor: DeukSu LEE, Paju-si (KR)

(73) Assignee: LG Display Co., Ltd., Seoul (KR)

(21) Appl. No.: 19/455,023

(22) Filed: Jan. 21, 2026

(30) Foreign Application Priority Data
Mar. 17, 2025 (KR) 10-2025-0034118

(51) Int. Cl. G06F 3/041; G06F 3/044

(52) U.S. Cl. CPC G06F 3/04184; G06F 3/04164; G06F 3/0443; G06F 3/0446; G06F 2203/04111

(57) ABSTRACT

A display device includes a plurality of display signal lines arranged on a substrate, a common electrode overlapping the plurality of display signal lines, and a compensation structure overlapping the common electrode and receiving a compensation signal. The compensation signal may have a voltage that fluctuates in synchronization with a voltage fluctuation timing of a display signal supplied to at least one display signal line among the plurality of display signal lines, and may have an antiphase relationship with the display signal. By applying the compensation signal to the compensation structure, voltage variations induced at the common electrode by the display signal may be reduced or canceled, allowing the common electrode to maintain a desired constant voltage state. This structure may also support stable touch sensing by limiting unwanted voltage variation at a touch sensor capacitively coupled to the common electrode.

### CROSS-REFERENCE TO RELATED APPLICATION

This application claims priority from Korean Patent Application No. 10-2025-0034118, filed on Mar. 17, 2025, which is hereby incorporated by reference for all purposes as if fully set forth herein.

### BACKGROUND

### Technical Field

Embodiments of the present disclosure relate to a display device.

### Description of the Related Art

A display panel of a display device may include a plurality of display signal lines whose voltages change over time and a common electrode with a constant voltage state for display operation.

If the voltage of at least one of the plurality of display signal lines changes, the common electrode may not maintain a constant voltage state. This may result in a deterioration in display quality.

Furthermore, the display panel of the display device may further include a touch sensor on the common electrode. In this case, if the voltage state of the common electrode is not maintained constant due to voltage fluctuations in at least one display signal line, the touch sensor may also have an undesirable voltage state, which may result in a deterioration in touch sensing quality.

### BRIEF SUMMARY

The present disclosure describes a display device in which voltage fluctuations on display signal lines (such as data or gate lines) can undesirably couple into the common electrode and the touch sensor through parasitic capacitances, generating noise that degrades both image quality and touch-sensing performance. Because the common electrode must ideally remain at a constant voltage, any ripple caused by display-signal transitions propagates upward to the touch layer, creating unstable touch-sensor voltages and reduced touch accuracy.

To eliminate this noise, the device introduces a compensation structure (compensation pattern)—a metal structure placed so that it is capacitively coupled to the common electrode but electrically isolated from the display signal lines. A compensation signal is applied to this pattern, synchronized with the timing of display-signal fluctuations but driven in antiphase. When the display-signal voltage rises, the compensation signal falls (and vice versa), generating an opposing capacitive noise component at the common electrode. By matching the capacitive coupling and voltage swing between the display lines and the compensation structure, these noise components cancel, allowing the common electrode to maintain its intended constant voltage.

The disclosure also provides various layout options for implementing the compensation structure-such as placing it in the same metal layer as the data lines or in a separate layer closer to the common electrode- and offers individual or group-driving schemes for applying compensation signals. A controller calculates the required compensation waveform based on image data differences between lines, enabling dynamic noise cancellation during display driving, including cases where touch sensing operates concurrently with image rendering. This structure improves display uniformity, enables stable touch sensing, and supports repairability of sub-pixels.

Embodiments of the present disclosure may provide a display device in which a common electrode can maintain a constant voltage even if a voltage fluctuation occurs in at least one display signal line during display driving.

Embodiments of the present disclosure may provide a display device in which a touch sensor can have a desired voltage state even if a voltage fluctuation occurs in at least one display signal line.

The benefits of the embodiments of the present disclosure are not limited to the benefits described in this specification, and other objects will be clearly understood by those skilled in the art from the description below.

A display device according to embodiments of the present disclosure may include a plurality of display signal lines arranged on a substrate, a common electrode arranged above the plurality of display signal lines and overlapping with the plurality of display signal lines, and a compensation structure (compensation pattern) arranged under the common electrode and overlapping with the common electrode and to which a compensation signal is applied. The compensation signal may have a voltage that fluctuates in synchronization with a voltage fluctuation timing of a display signal supplied to at least one display signal line among the plurality of display signal lines, and may have an antiphase relationship with the display signal.

A display device according to embodiments of the present disclosure may include a touch sensor layer supplied with a voltage having a first voltage fluctuation over time during a first driving period, a common electrode capacitively coupled to the touch sensor layer and supplied with a constant voltage during the first driving period, a display signal line capacitively coupled to the common electrode and supplied with a voltage having a second voltage fluctuation over time during the first driving period, and a metal pattern capacitively coupled to the common electrode and supplied with a voltage having a third voltage fluctuation synchronized with the second voltage fluctuation of the display signal line during the first driving period. A voltage of the metal pattern may decrease if a voltage of the display signal line increases, and the voltage of the metal pattern may increase if the voltage of the display signal line decreases.

According to embodiments of the present disclosure, it is possible to provide a display device having a structure that enables repair processing to normalize a defective sub-pixel.

According to embodiments of the present disclosure, it is possible to improve the display quality by maintaining a constant voltage of the common electrode through a noise compensation structure during the display driving, even if the voltage of at least one display signal line fluctuates.

According to embodiments of the present disclosure, it is possible to improve the touch sensing quality by ensuring that the touch sensor has a desired voltage state through a noise compensation structure during the display driving, even if the voltage of at least one display signal line fluctuates.

The effects of the embodiments of the present disclosure are not limited to the effects described in this specification, and other effects will be clearly understood by those skilled in the art from the description of the claims.

### BRIEF DESCRIPTION OF THE SEVERAL VIEWS OF THE DRAWINGS

The present disclosure will be more fully understood from the detailed description and accompanying drawings provided below, which are provided for illustration purposes only and are not intended to limit the present disclosure.

FIG. 1 illustrates a display device according to embodiments of the present disclosure.

FIG. 2 illustrates a display panel according to embodiments of the present disclosure.

FIG. 3 illustrates a touch sensor structure according to embodiments of the present disclosure.

FIG. 4 is a cross-sectional view of a display panel according to embodiments of the present disclosure.

FIG. 5 is a driving timing diagram of a display device according to embodiments of the present disclosure.

FIG. 6 illustrates a noise generation structure of a display panel according to embodiments of the present disclosure.

FIGS. 7 to 9 illustrate a noise compensation structure and noise compensation principle of a display panel according to embodiments of the present disclosure.

FIG. 10 illustrates a driving system for noise compensation of a display device according to embodiments of the present disclosure.

FIGS. 11 to 14 are plan views and cross-sectional views of a display panel with a noise compensation structure according to embodiments of the present disclosure.

FIGS. 15 to 17 illustrate data signals and compensation signals according to embodiments of the present disclosure.

FIG. 18 illustrates a group driving structure for a compensation pattern according to embodiments of the present disclosure.

FIG. 19 illustrates the first to third compensation signals applied to the first to third groups during group driving for a compensation pattern according to embodiments of the present disclosure.

FIG. 20 illustrates a driving system for group driving for a compensation pattern according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

To further elaborate, as used herein, the term “connected” is intended to have the broadest possible meaning. Specifically, the phrase “A is connected to B” encompasses both a direct connection—where no intervening components or elements are present- and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled” and “in contact” should be interpreted in the same manner.

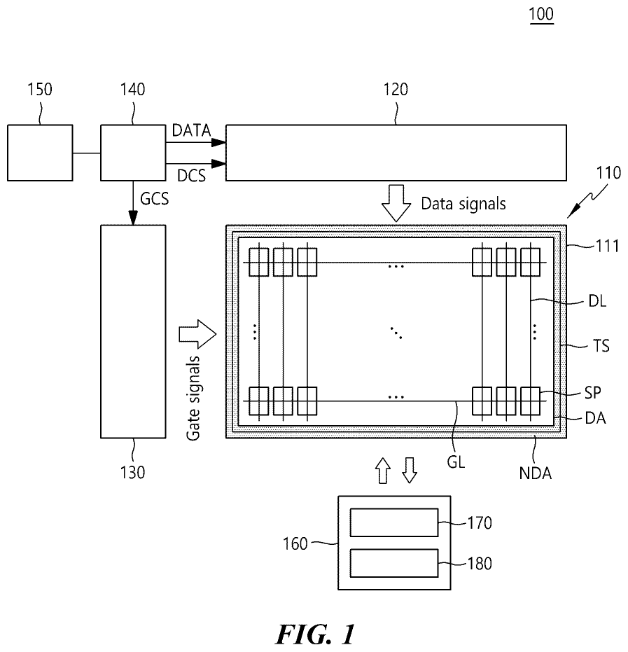

FIG. 1 illustrates a display device 100 according to embodiments of the present disclosure.

Referring to FIG. 1, a display device 100 according to embodiments of the present disclosure may include a display panel 110 and a driving circuit for driving the display panel 110. The driving circuit may include a data driving circuit 120, a gate driving circuit 130, and a controller 140.

The display panel 110 may include a display area DA where an image can be displayed, and a non-display area NDA that is an area outside the display area DA. The display panel 110 may include a substrate 111, a plurality of sub-pixels SP and a plurality of signal lines arranged on the substrate 111. The substrate 111 may include the display area DA and the non-display area NDA.

The display area DA may include a plurality of sub-pixels SP for image display. The non-display area NDA may include a pad area to which a driving circuit is connected.

The display device 100 may be a display device (e.g., a liquid crystal display, etc.) in which the display panel 110 does not emit light on its own, or a self-luminous display device that emits light on its own through light emitting devices arranged on the display panel 110.

If the display device 100 is a self-luminous display device, for example, the display device 100 may be an organic light-emitting display device in which the light emitting device is implemented as an organic light-emitting diode (OLED), an inorganic light-emitting display device in which the light emitting device is implemented as an inorganic-based light-emitting diode, a quantum dot display device in which the light emitting device is implemented as a quantum dot which is a semiconductor crystal emitting light by itself, or a micro LED display device or a mini LED display device.

Various types of display signal lines may be arranged on the substrate 111 of the display panel 110 to drive a plurality of sub-pixels SP. For example, the various types of display signal lines may include a plurality of data lines DL that transmit data signals (also referred to as data voltages or image signals) to a plurality of sub-pixels SP, and a plurality of gate lines GL that transmit gate signals (also referred to as scan signals) to a plurality of sub-pixels SP.

The data driving circuit 120 may receive digital image data DATA from the controller 140, convert the received image data DATA into analog data signals (i.e., data voltages), and output the converted data to a plurality of data lines DL.

The gate driving circuit 130 may receive a first gate voltage corresponding to a turn-on level voltage and a second gate voltage corresponding to a turn-off level voltage, along with various gate driving control signals GCS, generate gate signals including a section having the first gate voltage and a section having the second gate voltage for a predetermined period of time (e.g., one frame time), and supply the generated gate signals to a plurality of gate lines GL. For example, the turn-on level voltage may be a high level voltage, and the turn-off level voltage may be a low level voltage. In another example, the turn-on level voltage may be a low level voltage, and the turn-off level voltage may be a high level voltage.

The gate driving circuit 130 may be built into the display panel 110 as a gate-in-panel (GIP) type. The gate driving circuit 130 may be arranged in a non-display area NDA or a display area DA of the display panel 110.

The controller 140 may supply image data DATA to the data driving circuit 120 based on input image data received from a host system 150. The controller 140 may supply a data driving control signal DCS to the data driving circuit 120 and a gate driving control signal GCS to the gate driving circuit 130.

The display device 100 according to embodiments of the present disclosure may further include a touch sensor TS disposed in the display area DA and a touch sensing circuit 160 that senses the touch sensor TS to detect a touch.

The touch sensing circuit 160 may include a touch driving circuit 170 that drives and senses the touch sensor TS to generate and output touch sensing data, and a touch controller 180 that determines the presence or absence of a touch or touch coordinates using the touch sensing data.

The display device 100 according to embodiments of the present disclosure may be a terminal such as a smartphone or tablet, or a monitor or television (TV). However, the present disclosure is not limited thereto.

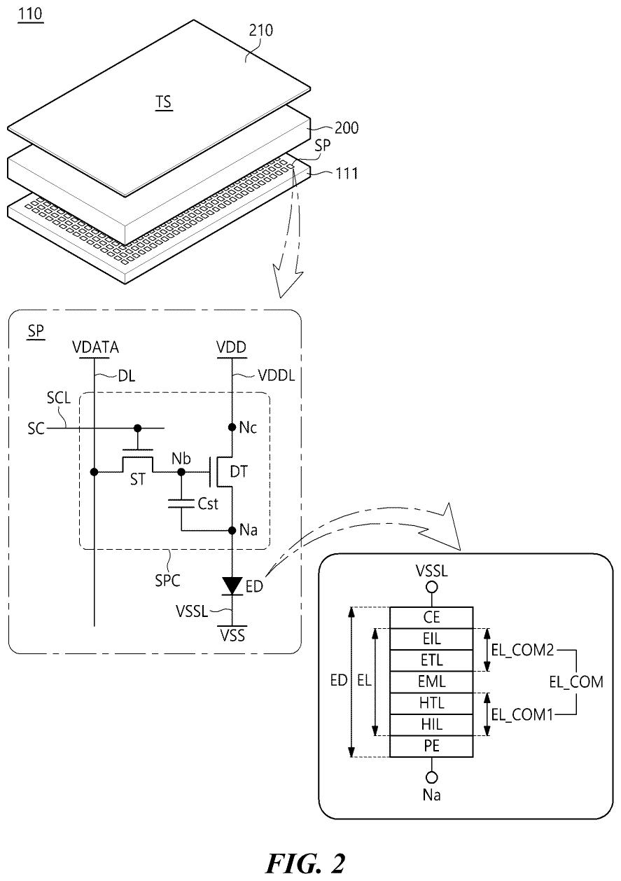

FIG. 2 illustrates a display panel 110 according to embodiments of the present disclosure.

Referring to FIG. 2, the display panel 110 according to embodiments of the present disclosure may include a substrate 111 on which a plurality of sub-pixels SP are arranged, and an encapsulation layer 200 on the substrate 111. The encapsulation layer 200 may also be referred to as an encapsulation substrate or an encapsulation portion.

Each of the plurality of sub-pixels SP of the display device 100 according to embodiments of the present disclosure may include a light emitting device ED and a sub-pixel circuit SPC for supplying a driving current to the light emitting device ED at a predetermined timing to drive the light emitting device ED.

The sub-pixel circuit SPC may include a driving transistor DT for driving a light emitting device ED, a scan transistor ST that turns on and off according to a scan signal SC, and a storage capacitor Cst for maintaining a constant voltage for a predetermined period of time.

A data signal VDATA which is an image signal, and a scan signal SC which is a type of gate signal may be applied to the sub-pixel SP. A common voltage may be applied to the sub-pixel SP. The common voltage may include a first common voltage VSS and a second common voltage VDD. For example, the first common voltage VSS may be a low-potential power supply voltage, and the second common voltage VDD may be a high-potential power supply voltage.

The light emitting device ED may include a pixel electrode PE, an intermediate layer EL, and a common electrode CE. The intermediate layer EL may be positioned between the pixel electrode PE and the common electrode CE. For example, the pixel electrode PE may be an electrode disposed in each sub-pixel SP, and the common electrode CE may be an electrode commonly disposed across a plurality of sub-pixels SP. For example, the pixel electrode PE may be an anode, and the common electrode CE may be a cathode. In another example, the pixel electrode PE may be a cathode, and the common electrode CE may be an anode. For example, the intermediate layer EL may include an organic material.

If the light emitting device ED is an organic light emitting device, the intermediate layer EL may include an emission layer EML and a common intermediate layer EL_COM. The common intermediate layer EL_COM may include a first common intermediate layer EL_COM1 between the pixel electrode PE and the emission layer EML, and a second common intermediate layer EL_COM2 between the emission layer EML and the common electrode CE. For example, the first common intermediate layer EL_COM1 may include a hole injection layer HIL and a hole transport layer HTL, and the second common intermediate layer EL_COM2 may include an electron transport layer ETL and an electron injection layer EIL.

The emission layer EML may be arranged for each sub-pixel SP or may be arranged in common across a plurality of sub-pixels SP, and the common intermediate layer EL_COM may be arranged in common across a plurality of sub-pixels SP.

For example, the common electrode CE may be electrically connected to a first common voltage line VSSL, which is a type of display power line. A first common voltage VSS, which is a type of common voltage, may be applied to the common electrode CE via the first common voltage line VSSL. The pixel electrode PE may be electrically connected, directly or indirectly, to a first node Na of the driving transistor DT of each sub-pixel SP. The first common voltage VSS may also be referred to as a low-potential power supply voltage or low-potential voltage, and the first common voltage line VSSL may also be referred to as a low-potential power supply voltage line or low-potential voltage line.

The driving transistor DT may be connected between a second common voltage line VDDL, which is another type of display power line, and a light emitting device ED. The driving transistor DT may include a first node Na, a second node Nb, and a third node Nc. The first node Na may be electrically connected to the light emitting device ED, a data signal VDATA may be applied to the second node Nb, and a second common voltage VDD, which is another type of common voltage, may be applied to the third node Nc from the second common voltage line VDDL. The driving transistor DT may be connected between the first node Na and the third node Nc. Here, the second common voltage VDD may also be referred to as a high-potential power supply voltage or a high-potential voltage, and the second common voltage line VDDL may also be referred to as a high-potential power supply voltage line or a high-potential voltage line. The second node Nb may be a gate node, the first node Na may be a source node or a drain node, and the third node Nc may be a drain node or a source node.

The scan transistor ST may be a switching transistor for transmitting a data signal VDATA, which is an image signal, to the second node Nb, which is the gate node of the driving transistor DT. The scan transistor ST may be turned on and off by a scan signal SC, which is a type of gate signal applied through a scan line SCL, which is a type of gate line GL, thereby controlling the electrical connection between the second node Nb of the driving transistor DT and the data line DL. The scan transistor ST may be connected between the data line DL and the second node Nb of the driving transistor DT.

The storage capacitor Cst may be electrically connected between the first node Na and the second node Nb of the driving transistor DT.

Each of the driving transistor DT and the scan transistor ST may be an n-type or p-type transistor. Unlike the circuit illustrated in FIG. 2, the sub-pixel circuit SPC may further include one or more transistors and/or one or more capacitors. The display panel 110 may have a top-emission or bottom-emission structure.

Since the circuit elements within each sub-pixel SP (e.g., the light emitting device ED comprising an organic material) are vulnerable to external moisture or oxygen, an encapsulation layer 200 may be disposed on the light emitting device ED. The encapsulation layer 200 may be configured in various forms to prevent the light emitting devices ED from coming into contact with moisture or oxygen. For example, the encapsulation layer 200 may be composed of two or more layers in which organic and inorganic films are alternately stacked.

The display device 100 according to embodiments of the present disclosure may further include a touch sensor layer 210 on which a touch sensor TS is formed to provide a touch sensing function. The touch sensor TS may be composed of a plurality of touch electrodes.

As an example, the touch sensor layer 210 may be disposed outside the display panel 110 and may be configured as a separate touch panel from the display panel 110. Alternatively, the touch sensor layer 210 may be embedded in the display panel 110. In this case, the touch sensor layer 210 may be disposed on the encapsulation layer 200.

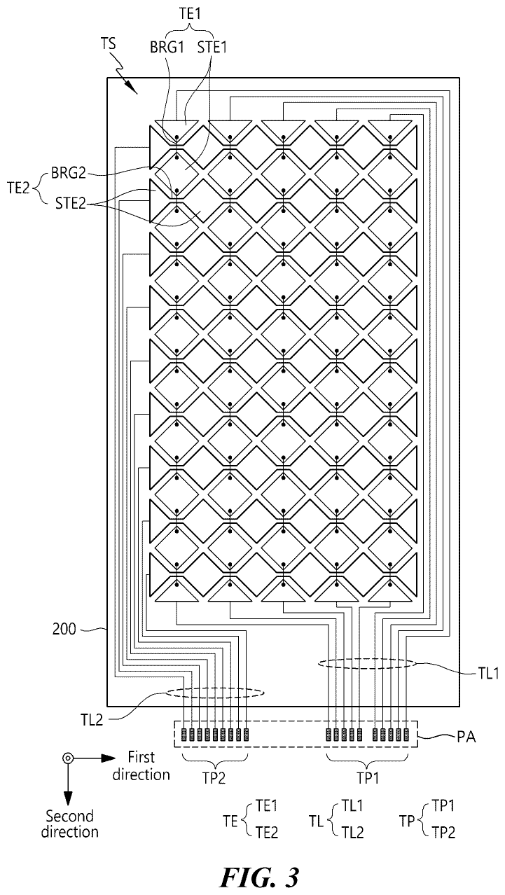

FIG. 3 illustrates a touch sensor structure according to embodiments of the present disclosure.

Referring to FIG. 3, a touch sensor TS according to embodiments of the present disclosure may include a plurality of touch electrodes TE. For example, the plurality of touch electrodes TE may include a plurality of first touch electrodes TE1 and a plurality of second touch electrodes TE2.

Each of the plurality of first touch electrodes TE1 may include two or more first sub-touch electrodes STE1 arranged in the same column (or row) and one or more first bridge electrodes BRG1 electrically connecting the two first sub-touch electrodes STE1. For example, two or more first sub-touch electrodes STE1 may be arranged within a second touch metal layer, and one or more first bridge electrodes BRG1 may be arranged within a first touch metal layer different from the second touch metal layer. As another example, two or more first sub-touch electrodes STE1 and one or more first bridge electrodes BRG1 may be an integrated touch metal (e.g., a second touch metal) and may be disposed within a second touch metal layer.

Each of the plurality of second touch electrodes TE2 may include two or more second sub-touch electrodes STE2 arranged in the same row (or column) and one or more second bridge electrodes BRG2 electrically connecting the two second sub-touch electrodes STE2. For example, the two or more second sub-touch electrodes STE2 may be arranged within a second touch metal layer, and the one or more second bridge electrodes BRG2 may be arranged within a first touch metal layer. In another example, the two or more second sub-touch electrodes STE2 and the one or more second bridge electrodes BRG2 may be integrated touch metal (e.g., second touch metal) and may be arranged within a second touch metal layer.

In the region where the first touch electrodes TE1 and the second touch electrodes TE2 intersect (e.g., touch electrode intersection region), the first bridge electrodes BRG1 and the second bridge electrodes BRG2 may intersect each other and be arranged on different layers.

The touch sensor structure according to embodiments of the present disclosure may further include a plurality of touch routing lines TL including a plurality of first touch routing lines TL1 and a plurality of second touch routing lines TL2, and a plurality of touch pads TP including a plurality of first touch pads TP1 and a plurality of second touch pads TP2.

Each of the plurality of first touch electrodes TE1 may be electrically connected to the corresponding first touch pad TP1 through one or more first touch routing lines TL1, and each of the plurality of second touch electrodes TE2 may be electrically connected to the corresponding second touch pad TP2 through one or more second touch routing lines TL2.

Each of the plurality of first touch routing lines TL1 may be disposed on the encapsulation layer 200 and extend to the periphery of the encapsulation layer 200, thereby being electrically connected to the plurality of first touch pads TP1 within a pad area PA located at the periphery of the encapsulation layer 200. Each of the plurality of second touch routing lines TL2 may be disposed on the encapsulation layer 200 and extend to the periphery of the encapsulation layer 200, thereby being electrically connected to a plurality of second touch pads TP2 within a pad area PA located at the periphery of the encapsulation layer 200.

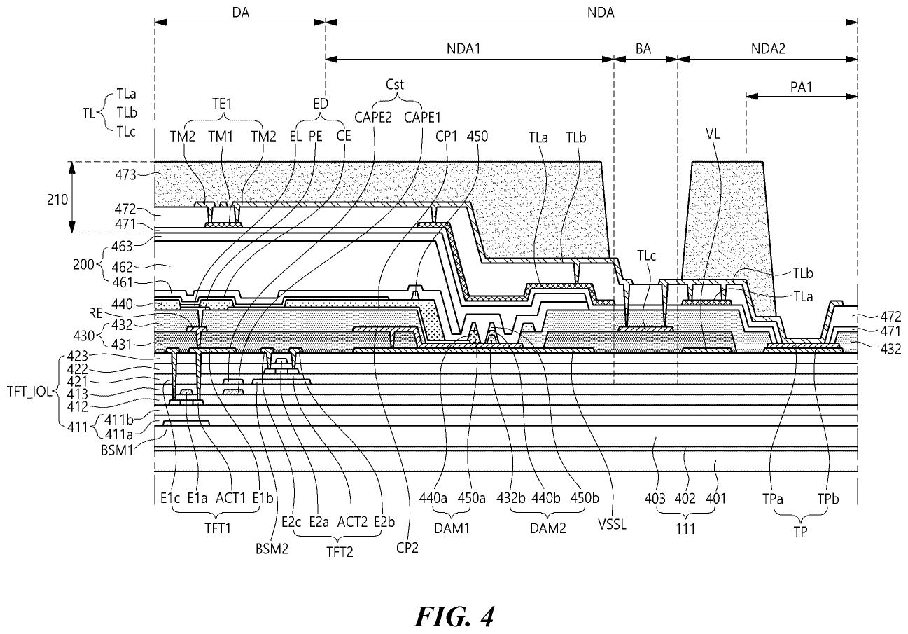

FIG. 4 is a cross-sectional view of a display panel 110 according to embodiments of the present disclosure.

Referring to FIG. 4, the display panel 110 according to embodiments of the present disclosure may include a substrate 111, a transistor unit, a light emitting device unit, and an encapsulation unit.

The substrate 111 may be a single layer or a multilayer. If the substrate 111 is a multilayer, the substrate 111 may include a first substrate 401, a substrate intermediate layer 402, and a second substrate 403. For example, the first substrate 401 and the second substrate 403 may each be polyimide (PI) layers, and the substrate intermediate layer 402 may be an inorganic insulating layer.

The substrate intermediate layer 402 is positioned between the first substrate 401 and the second substrate 403 and may block moisture from penetrating upward through the first substrate 401.

A transistor insulating layer stack TFT_IOL may include insulating layers necessary to form the transistors TFT1 and TFT2. For example, the insulating layers included in the transistor insulating layer stack TFT_IOL may be inorganic layers.

The transistor unit may include the transistor insulating layer stack TFT_IOL on the substrate 111, transistors TFT1 and TFT2, storage capacitors Cst, and various electrodes or signal lines. The transistors may include a first transistor TFT1 and a second transistor TFT2.

The first transistor TFT1 may include a first active layer ACT1, a first electrode Ela, a second electrode Elb, and a third electrode Elc. The first electrode Ela may be a gate electrode, the second electrode Elb may be a source electrode or a drain electrode, the third electrode Elc may be a drain electrode or a source electrode, and the first active layer ACT1 may include a first semiconductor material.

The second transistor TFT2 may include a second active layer ACT2, a fourth electrode E2a, a fifth electrode E2b, and a sixth electrode E2c. The fourth electrode E2a may be a gate electrode, the fifth electrode E2b may be a source electrode or drain electrode, the sixth electrode E2c may be a drain electrode or source electrode, and the second active layer ACT2 may include a second semiconductor material that is the same as or different from the first semiconductor material. The second active layer ACT2 of the second transistor TFT2 may be positioned higher from the substrate 111 than the first active layer ACT1 of the first transistor TFT1. For example, the first semiconductor material may include low-temperature polysilicon (LTPS), and the second semiconductor material may include an oxide semiconductor material.

The storage capacitor Cst may include a first capacitor electrode CAPE1 and a second capacitor electrode CAPE2.

A planarization layer 430 may be disposed between the transistor unit and the light emitting device unit. The planarization layer 430 may be a single layer or a plurality of layers. For example, the planarization layer 430 may include a first planarization layer 431 and a second planarization layer 432. As another example, the planarization layer 430 may further include a third planarization layer in addition to the first and second planarization layers 431 and 432.

The light emitting device unit may include a plurality of light emitting devices ED arranged on the planarization layer 430. The encapsulation unit may be positioned on the light emitting device unit and may include an encapsulation layer 200 on the plurality of light emitting devices ED. The encapsulation layer 200 may be a single layer or a plurality of layers.

In addition to the encapsulation layer 200, the encapsulation unit may further include a dam unit to prevent the material constituting the encapsulation layer 200 from overflowing. For example, the dam unit may include a first dam DAM1 and a second dam DAM2. The first dam DAM1 may be positioned closer to the display area DA than the second dam DAM2. Each of the first dam DAM1 and the second dam DAM2 may be configured to include at least one of an organic insulating material forming the second planarization layer 432, an organic insulating material forming a bank 440, and an organic insulating material forming a spacer 450. For example, the first dam DAM1 may include a first lower dam 440a including an organic insulating material forming the bank 440, and a first upper dam 450a including an organic insulating material forming the spacer 450. The second dam DAM2 may include a second lower dam 432b including an organic insulating material forming a second planarization layer 432, a second intermediate dam 440b including an organic insulating material forming the bank 440, and a third upper dam 450b comprising an organic insulating material forming the spacer 450.

The structure of the display panel 110 will be described in more detail below.

A first buffer layer 411 may be disposed on the substrate 111. The first buffer layer 411 may be a single layer or a plurality of layers. For example, the first buffer layer 411 may include a lower buffer layer 411a and an upper buffer layer 411b.

A first active layer ACT1 may be disposed on the first buffer layer 411. The first active layer ACT1 may include a channel region in which a channel is formed, a source connection region on one side of the channel region, and a drain connection region on the other side of the channel region.

A first gate insulating layer 412 may be disposed on the first active layer ACT1 of the first transistor TFT1, a first gate electrode Ela may be disposed on the first gate insulating layer 412, and a first interlayer insulating layer 413 may be disposed on the first gate electrode Ela. The first gate electrode Ela may be disposed within a first gate metal layer formed of a first gate metal.

A second buffer layer 421 may be disposed on the first interlayer insulating layer 413.

A second active layer ACT2 of the second transistor TFT2 may be disposed on the second buffer layer 421. The second active layer ACT2 may include a channel region in which a channel is formed, a source connection region on one side of the channel region, and a drain connection region on the other side of the channel region.

A second gate insulating layer 422 may be disposed on the second active layer ACT2. A second gate electrode E2a may be disposed on the second gate insulating layer 422. A second interlayer insulating layer 423 may be disposed on the second gate electrode E2a. The second gate electrode E2a may be disposed within a second gate metal layer formed of a second gate metal.

A first source electrode E1b, a first drain electrode E1c, a second source electrode E2b, and a second drain electrode E2c may be disposed on the second interlayer insulating layer 423. The first source electrode E1b, the first drain electrode E1c, the second source electrode E2b, and the second drain electrode E2c may be disposed within a first source-drain metal layer formed of a first source-drain metal.

The first source electrode E1b and the first drain electrode E1c may be connected to the source connection region and the drain connection region of the first active layer ACT1, respectively, through holes in the second interlayer insulating layer 423, the second gate insulating layer 422, the second buffer layer 421, the first interlayer insulating layer 413, and the first gate insulating layer 412. The second source electrode E2b and the second drain electrode E2c may be connected to the source connection region and the drain connection region of the second active layer ACT2, respectively, through holes in the second interlayer insulating layer 423 and the second gate insulating layer 422.

The storage capacitor Cst may be formed by the first capacitor electrode CAPE1 and the second capacitor electrode CAPE2. For example, the first capacitor electrode CAPE1 may be disposed within the first gate metal layer in which the first gate electrode Ela is disposed (formed/included) on the first gate insulating layer 412. For example, the second capacitor electrode CAPE2 may be disposed on the first interlayer insulating layer 413.

The transistor unit may further include at least one of a first shield pattern BSM1 overlapping with the first active layer ACT1 and a second shield pattern BSM2 overlapping with the second active layer ACT2. For example, the first shield pattern BSM1 may be disposed between the substrate 111 and the first buffer layer 411, or between the lower buffer layer 411a and the upper buffer layer 411b. For example, the second shield pattern BSM2 may be disposed within the same metal layer as the second capacitor CAPE2. For another example, the second shield pattern BSM2 may be disposed within the same first gate metal layer as the first gate electrode Ela.

The planarization layer 430 may be an organic layer including an organic insulating material. For example, the planarization layer 430 may be composed of a single layer. As another example, the planarization layer 430 may include two layers. The planarization layer 430 may include first and second planarization layers 431 and 432, and in some cases, may further include a third planarization layer.

The first planarization layer 431 may be disposed on the first source electrode E1b and the first drain electrode E1c, and the second source electrode E2b and the second drain electrode E2c.

A connection electrode RE may electrically connect the first source electrode E1b and the pixel electrode PE through a hole in the first planarization layer 431. The connection electrode RE may be disposed within a second source-drain metal layer on the first planarization layer 431. The second source-drain metal layer may be composed of a second source-drain metal.

The second planarization layer 432 may be disposed on the connection electrode RE. The light emitting device ED may be formed on the second planarization layer 432.

The pixel electrode PE may be disposed on the second planarization layer 432 and electrically connected to the connection electrode RE through a hole in the second planarization layer 432.

The bank 440 may be disposed on the pixel electrode PE. To form a light emission area, the bank 440 may have an opening that overlaps with a portion of the pixel electrode PE. For example, the bank 440 may be composed of an organic material. If the bank 440 is composed of a material including a black pigment or a black dye, the bank 440 may be a black bank. The spacer 450 may be additionally positioned on the bank 440.

The intermediate layer EL of the light emitting device ED may be positioned on a portion of the pixel electrode PE and the bank 440. The common electrode CE may be positioned on the intermediate layer EL.

The encapsulation layer 200 may be positioned on the common electrode CE and may be composed of a single layer or a plurality of layers. For example, the encapsulation layer 200 may include a first encapsulation layer 461, a second encapsulation layer 462, and a third encapsulation layer 463. The first encapsulation layer 461 and the third encapsulation layer 463 may include inorganic encapsulation layers, and the second encapsulation layer 462 may include an organic encapsulation layer.

The display panel 110 may further include a touch sensor layer 210 disposed on the encapsulation layer 200 and having a touch sensor formed thereon. The touch sensor layer 210 may include a plurality of touch electrodes TE corresponding to the touch sensors.

The plurality of touch electrodes TE may be composed of at least one touch metal layer. For example, the touch sensor layer 210 may include a first touch metal layer, a second touch metal layer, and a touch interlayer insulating layer 472 between the first and second touch metal layers. The metal disposed within the first touch metal layer may be referred to as a first touch metal TM1, and the metal disposed within the second touch metal layer may be referred to as a second touch metal TM2.

For example, the first touch metal layer may be a bridge metal layer, and the second touch metal layer may be a sensor metal layer. In this case, the plurality of second touch metals TM2 disposed within the second touch metal layer may be sensor metals forming a touch sensor, and the plurality of first touch metals TM1 disposed within the first touch metal layer may be bridge metals electrically connecting the plurality of second touch metals TM2. For example, two or more second touch metals TM2 and at least one first touch metal TM1 may constitute one first touch electrode TE1. In this case, two or more second touch metals TM2 may be electrically connected by at least one first touch metal TM1.

The touch sensor layer 210 may further include a touch buffer layer 471 disposed on the encapsulation layer 200. The touch buffer layer 471 may be disposed between the encapsulation layer 200 and the touch metal layer. For example, a first touch metal layer may be disposed on the touch buffer layer 471, and a touch interlayer insulating layer 472 may be disposed on the first touch metal layer.

The touch sensor layer 210 may further include a touch protection layer 473 disposed on the second touch metal layer.

For example, the touch buffer layer 471 may be an inorganic layer including an inorganic insulating material or an organic layer including an organic insulating material. The touch interlayer insulating layer 472 may be an inorganic layer including an inorganic insulating material or an organic layer including an organic insulating material. The touch protection layer 473 may be an organic layer including an organic insulating material.

For example, at least one of the touch buffer layer 471 and the touch interlayer insulating layer 472 may extend from the display area DA to the non-display area NDA. The touch protection layer 473 may extend from the display area DA to the non-display area NDA.

The touch routing line TL may electrically connect the touch electrode TE and the touch pad TP. The touch routing line TL may be composed of at least one of a first touch metal TM1 and a second touch metal TM2. For example, the touch routing line TL may include a wiring section TLa composed of the first touch metal TM1, a wiring section TLb composed of the second touch metal TM2, and a wiring section TLc composed of the second source-drain metal.

The touch routing line TL may be arranged along an inclined surface of the encapsulation layer 200 and may extend past an upper portion of the dams DAM1 and DAM2 to the touch pad TP.

Each of the plurality of touch electrodes TE may be a mesh-type electrode having a plurality of openings. In this case, each of the plurality of touch electrodes TE may be composed of at least one second touch metal TM2.

The plurality of first touch metals TM1 and the plurality of second touch metals TM2 may be arranged so as not to overlap with the light emitting device ED and may overlap with the bank 440. Accordingly, the light-emitting efficiency of the light emitting device ED may be improved.

The display panel 110 may further include a connection pattern that electrically connects the common electrode CE and the first common voltage line VSSL. The connection pattern may include a first connection pattern CP1 made of the same metal as the pixel electrode PE. The connection pattern may further include a second connection pattern CP2 that connects the first connection pattern CP1 and the first common voltage line VSSL. For example, the second connection pattern CP2 may be made of a second source-drain metal. The first common voltage line VSSL may be made of a first source-drain metal. At least a portion of the first connection pattern CP1 and the second connection pattern CP2 may be disposed in a first non-display area NDA1.

At least one of the first common voltage line VSSL and the second connection pattern CP2 may pass beneath at least one of the first dam DAM1 and the second dam DAM2. Accordingly, at least one of the first common voltage line VSSL and the second connection pattern CP2 may overlap with at least one of the first dam DAM1 and the second dam DAM2. Various power lines VL other than the first common voltage line VSSL may be disposed in the non-display area NDA.

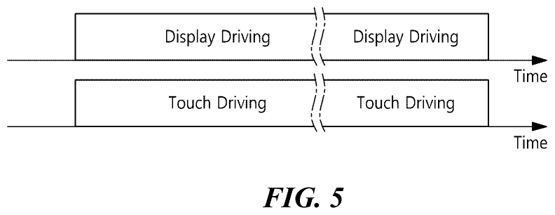

FIG. 5 is a driving timing diagram of a display device 100 according to embodiments of the present disclosure.

The display device 100 according to embodiments of the present disclosure may perform a touch sensing operation while performing a display driving operation for displaying an image. That is, in the display device 100, the display driving and touch driving may be performed simultaneously.

Alternatively, in the display device 100 according to embodiments of the present disclosure, the display driving operation and touch sensing operation may be performed at different times.

Meanwhile, during display driving, a voltage of a plurality of display signal lines used for display driving may fluctuate over time, and the common electrode CE used for display driving is required to be maintain a constant voltage. However, if the voltage of at least one of a plurality of display signal lines fluctuates during display driving, the common electrode CE may not be able to maintain a constant voltage, and further, the touch sensor TS may experience an undesirable voltage state.

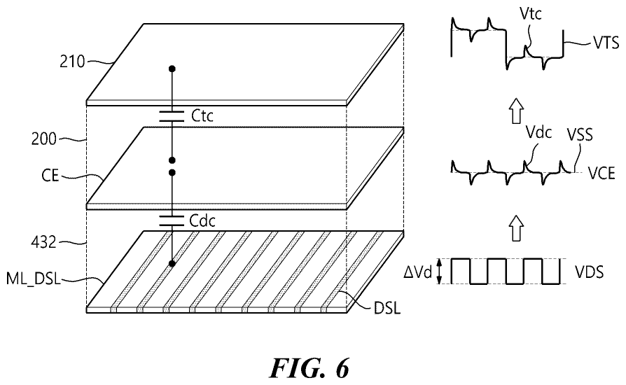

Hereinafter, it will be described the reason (e.g., noise generation structure) that the voltage of the common electrode CE cannot be maintained constant and the touch sensor TS also experience an undesirable voltage state due to the fluctuation of the voltage of the display signal line with reference to FIG. 6.

FIG. 6 illustrates a structure in which noise is generated in a common electrode CE of a display panel 110 according to embodiments of the present disclosure.

A display panel 110 according to embodiments of the present disclosure may include a plurality of display signal lines DSL and a common electrode CE disposed on the plurality of display signal lines DSL. The plurality of display signal lines DSL may be disposed within a display signal line layer ML_DSL.

For example, the plurality of display signal lines DSL may include a plurality of data lines DL and/or a plurality of gate lines GL.

If the display signal lines DSL are data lines DL, the display signal line layer ML_DSL may be a metal layer in which the data lines DL are disposed (formed/included). For example, the metal layer in which the data line DL is arranged (formed/included) may be a second source-drain metal layer, in which the connection electrode RE of FIG. 4 is arranged (formed/included), and which vertically overlaps with the common electrode CE and can be capacitively coupled to the common electrode CE.

If the display signal line DSL is a gate line GL, the display signal line layer ML_DSL may be a metal layer in which the gate line GL is arranged (formed/included). For example, the metal layer in which the gate line GL is arranged (formed/included) may be a second gate metal layer, in which the gate electrode E2a of the second transistor TFT2 of FIG. 4 is arranged (formed/included), and which vertically overlaps with the common electrode CE and can be capacitively coupled to the common electrode CE.

An insulating layer (e.g., the second planarization layer 432 of FIG. 4, etc.) may be arranged between the display signal line DSL and the common electrode CE. Accordingly, the display signal line DSL and the common electrode CE can be capacitively coupled, and a first capacitor Cdc may be formed between the display signal line DSL and the common electrode CE.

A touch sensor layer 210 may be disposed on the common electrode CE. An insulating layer (e.g., the encapsulation layer 200 of FIG. 4) may be disposed between the touch sensor layer 210 and the common electrode CE. Accordingly, the touch sensor layer 210 and the common electrode CE may be capacitively coupled, and a second capacitor Ctc may be formed between the touch sensor layer 210 and the common electrode CE.

The first capacitor Cdc and the second capacitor Ctc may be a type of parasitic capacitor. The first capacitor Cdc may generate a first noise Vdc at the common electrode CE, and the second capacitor Ctc may generate a second noise Vtc at the touch sensor layer 210.

When driving a display, a display signal VDS whose voltage fluctuates over time may be applied to the display signal line DSL. That is, when driving a display, the display signal line DSL may be in a voltage state where the voltage fluctuates over time.

The display signal VDS may fluctuate in voltage at regular intervals. For example, the voltage fluctuation period of the display signal VDS may be one horizontal time. For example, the voltage of the display signal VDS may fluctuate whenever a sub-pixel line (e.g., a sub-pixel row in FIG. 1) driven within a frame changes.

The voltage fluctuation value ΔVd of the display signal VDS may vary depending on the image. The voltage fluctuation of the display signal VDS, which is unavoidable during display driving, may induce first noise Vdc in the common electrode CE capacitively coupled to the display signal line DSL. Here, the first noise Vdc may have a voltage higher than the first common voltage VSS when the voltage of the display signal VDS increases, and a voltage lower than the first common voltage VSS when the voltage of the display signal VDS decreases. The first noise Vdc may also be referred to as ripple noise.

The first noise Vdc may be an unwanted voltage (i.e., noise component) generated at the common electrode CE due to the influence of the display signal line DSL. Since a first capacitor Cdc is formed between the display signal line DSL and the common electrode CE, i.e., since the display signal line DSL and the common electrode CE are capacitively coupled, voltage fluctuations at the display signal line DSL may be generated as the first noise Vdc at the common electrode CE. As a result, the common electrode CE cannot maintain the first common voltage VSS, which is a constant voltage, and may have a voltage VCE that is a first noise Vdc added to the first common voltage VSS. In embodiments of the present disclosure, the voltage fluctuation of the display signal line DSL may also refer to the voltage fluctuation of the display signal VDS applied to the display signal line DSL.

In this way, during display operation, the first noise Vdc generated at the common electrode CE due to the voltage fluctuation of the display signal VDS applied to the display signal line DSL may also induce a second noise Vtc at the touch sensor layer 210 capacitively coupled to the common electrode CE.

The second noise Vtc may be an unwanted voltage (i.e., noise component) generated at the touch sensor layer 210 due to the influence of the common electrode CE. Since a second capacitor Ctc is formed between the touch sensor layer 210 and the common electrode CE, i.e., since the touch sensor layer 210 and the common electrode CE are capacitively coupled, voltage fluctuations at the common electrode CE may be generated as the second noise Vtc at the touch sensor layer 210. Accordingly, at least some of the plurality of touch electrodes TE formed on the touch sensor layer 210 may be in a state where an abnormal touch signal VTS is applied. The abnormal touch signal VTS may have a voltage state in which the second noise Vtc is added. The second noise Vtc may be in a state similar to the first noise Vdc.

As described above, during display operation, voltage fluctuations in the display signal VDS applied to the display signal line DSL may generate first noise Vdc at the common electrode CE. The first noise Vdc generated at the common electrode CE may generate the second noise Vtc at the touch sensor layer 210.

For display driving, voltage fluctuations in the display signal VDS applied to the display signal line DSL are necessary for image display, but which may generate the first noise Vdc at the common electrode CE, thereby degrading image quality.

The first noise Vdc generated at the common electrode CE may generate the second noise Vtc at the touch sensor layer 210, thereby degrading touch sensing quality. This problem can become even more serious in the case that the display device 100 performs both display driving and touch driving simultaneously.

Therefore, the display device 100 according to embodiments of the present disclosure may include a noise compensation structure and may provide a driving method utilizing the same.

According to the noise compensation structure and driving method utilizing the same according to embodiments of the present disclosure, if the voltage of the display signal line DSL fluctuates during display driving, noise at the common electrode CE can be reduced or eliminated, and noise at the touch sensor layer 210 can be reduced or eliminated. Accordingly, image quality and touch sensing quality can be improved.

The noise compensation structure and driving method utilizing the same according to embodiments of the present disclosure can be even more effective in a case in which the display driving and touch driving are performed simultaneously.

In the following description, for convenience of explanation, the display signal line DSL may be described as a data line DL. Accordingly, the data line DL may be referred to as a display signal line, and the data signal VDATA supplied to the data line DL may also be referred to as a display signal. In the following description, reference may also be made to FIGS. 1 to 6.

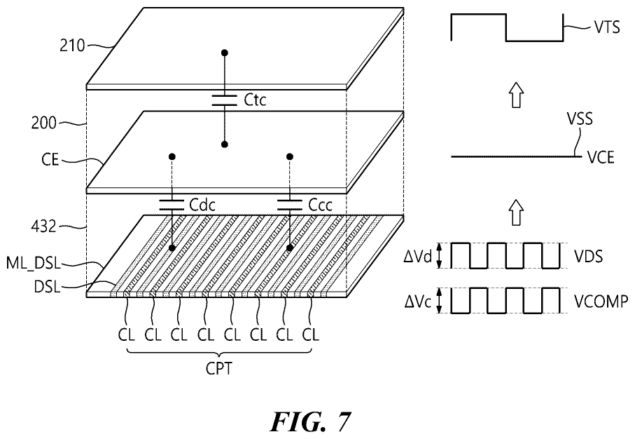

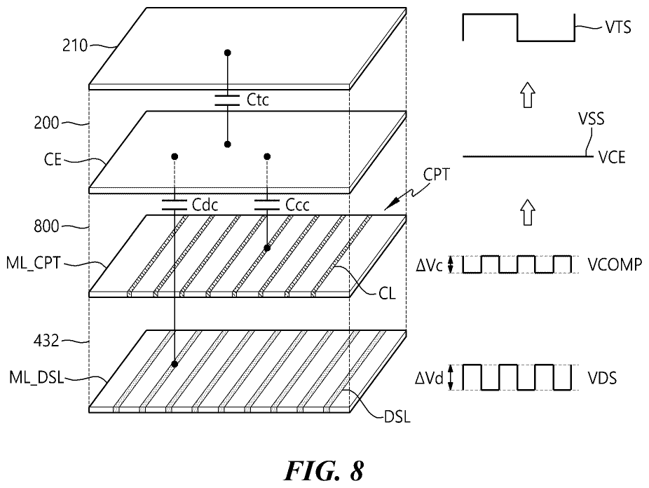

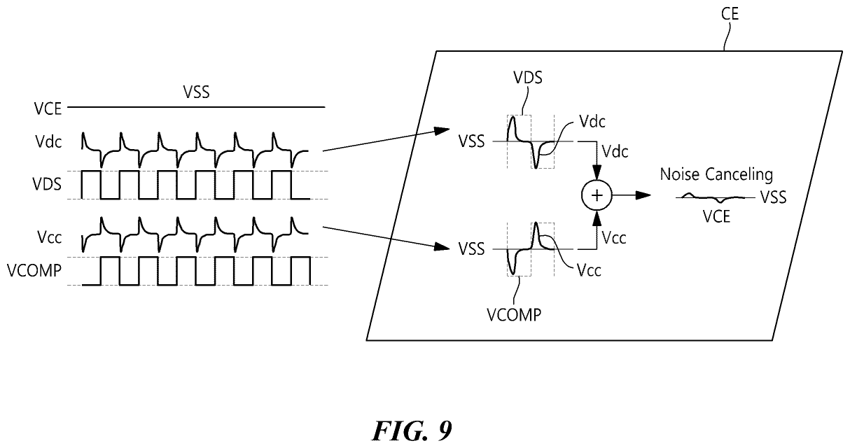

FIGS. 7 and 8 illustrate a noise compensation structure of a display panel 110 according to embodiments of the present disclosure, and FIG. 9 illustrates a noise compensation principle according to embodiments of the present disclosure.

Referring to FIGS. 7 and 8, a display panel 110 according to embodiments of the present disclosure may include a plurality of display signal lines DSL arranged on a substrate 111, and a common electrode CE arranged on the plurality of display signal lines DSL and vertically overlapping with the plurality of display signal lines DSL.

The display panel 110 according to embodiments of the present disclosure may include a compensation pattern CPT as a compensation structure (noise compensation structure). For example, the compensation pattern CPT may be arranged in the display area DA. For another example, the compensation pattern CPT may be arranged in the non-display area NDA. For another example, the compensation pattern CPT may be arranged in both the display area DA and the non-display area NDA. In this specification, the compensation pattern CPT may also be referred to as a metal pattern.

The compensation pattern CPT may vertically overlap with the common electrode CE. Accordingly, the compensation pattern CPT and the common electrode CE may be capacitively coupled. Accordingly, a third capacitor Ccc may be formed between the compensation pattern CPT and the common electrode CE.

A compensation signal VCOMP whose voltage (or voltage level) varies over time may be applied to the compensation pattern CPT. The compensation signal VCOMP may vary in voltage in synchronization with a voltage fluctuation timing of the display signal VDS supplied to at least one of the plurality of display signal lines DSL. Furthermore, the compensation signal VCOMP may have an antiphase relationship with the display signal VDS.

For example, the display signal line DSL may be a data line DL. In this case, the display signal line layer ML_DSL may be a metal layer in which the data line DL is arranged (formed/included). For example, the metal layer in which the data line DL is arranged (formed/included) may be a second source-drain metal layer, in which the connection electrode RE of FIG. 4 is arranged (formed/included), vertically overlapping with the common electrode CE and capacitively coupled to the common electrode CE.

For another example, the display signal line DSL may be a gate line GL. In this case, the display signal line layer ML_DSL may be a metal layer in which the gate line GL is arranged (formed/included). For example, the metal layer in which the gate line GL is arranged (formed/included) may be a second gate metal layer, in which the gate electrode E2a of the second transistor TFT2 of FIG. 4 is arranged (formed/included), vertically overlapping with the common electrode CE and capacitively coupled to the common electrode CE.

For example, the voltage fluctuation value ΔVc of the compensation signal VCOMP may be the same as or different from the voltage fluctuation value ΔVd of the display signal VDS. Synchronizing the voltage fluctuation timing of the compensation signal VCOMP with the voltage fluctuation timing of the display signal VDS may mean that a voltage fluctuation period of the compensation signal VCOMP corresponds to a voltage fluctuation period of the display signal VDS.

Referring to FIGS. 7 and 8, an encapsulation layer 200 may be disposed on the common electrode CE, and a touch sensor layer 210 may be disposed on the encapsulation layer 200, thereby forming a second capacitor Ctc between the common electrode CE and the touch sensor layer 210. The touch sensor layer 210 may vertically overlap with the common electrode CE and may also vertically overlap with at least a portion of the compensation pattern CPT.

Referring to FIG. 7, the compensation pattern CPT may be disposed within the same metal layer (e.g., display signal line layer ML_DSL) as the plurality of display signal lines DSL. For example, the display signal line layer ML_DSL in which the plurality of display signal lines DSL and the compensation pattern CPT are disposed (formed/included) may be a second source-drain metal layer in which the data lines DL are disposed (formed/included). As another example, the display signal line layer ML_DSL in which the plurality of display signal lines DSL and the compensation pattern CPT are disposed (formed/included) may be a second gate metal layer.

In this case, an insulating layer disposed between the display signal line layer ML_DSL in which the plurality of display signal lines DSL and the compensation pattern CPT are disposed (formed/included) and the common electrode CE may include a second planarization layer 432. A first capacitor Cdc may be formed between a plurality of display signal lines DSL and a common electrode CE with a second planarization layer 432 interposed therebetween, and a third capacitor Ccc may be formed between a compensation pattern CPT and the common electrode CE with a second planarization layer 432 interposed therebetween.

Referring to FIG. 8, the compensation pattern CPT may be disposed within a metal layer (e.g., compensation pattern layer ML_CPT) different from the metal layer (e.g., display signal line layer ML_DSL) in which the plurality of display signal lines DSL are disposed (formed/included). For example, the compensation pattern CPT may be disposed between the plurality of display signal lines DSL and the common electrode CE. That is, the compensation pattern layer ML_CPT on which the compensation pattern CPT is disposed may be a metal layer between the display signal line layer ML_DSL and the common electrode CE.

In this case, a third planarization layer 800 may be disposed between the compensation pattern layer ML_CPT in which the compensation pattern CPT is disposed (formed/included) and the common electrode CE, as an example of an additional insulating layer. Accordingly, a third capacitor Ccc may be formed between the plurality of compensation patterns CPT and the common electrode CE with the third planarization layer 800 interposed therebetween. In addition, the insulating layer disposed between the display signal line layer ML_DSL in which the plurality of display signal lines DSL are disposed (formed/included) and the common electrode CE may include a second planarization layer 432 and a third planarization layer 800. A first capacitor Cdc may be formed between the plurality of display signal lines DSL and the common electrode CE with the second planarization layer 432 and the third planarization layer 800 interposed therebetween.

Referring to FIGS. 7 and 8, while the display signal VDS is applied to the display signal line DSL, the compensation signal VCOMP may be applied to the compensation pattern CPT, thereby preventing or reducing noise from occurring at the common electrode CE forming the first capacitor Cdc with the display signal line DSL. Accordingly, the voltage VCE of the common electrode CE can stably maintain the first common voltage VSS, which is a constant voltage supplied from the circuit. As a result, the normal voltage state of the common electrode CE can improve image quality (i.e., display quality).

Referring to FIGS. 7 and 8, since noise is prevented or reduced at the common electrode CE, it is possible to prevent or reduce a noise Vtc at the touch sensor layer 210. Accordingly, a desired touch signal VTS can be normally applied to the touch sensor layer 210. As a result, the normal voltage state (i.e., touch driving state) of the touch sensor layer 210 can improve touch sensing quality (or touch sensitivity).

Referring to FIGS. 7 and 8, for example, the compensation pattern CPT may include at least one compensation line CL. Hereinafter, a case in which the compensation pattern CPT includes a plurality of compensation lines CL will be described as an example.

As an example, each of the plurality of compensation lines CL may have a line width corresponding to or identical to a line width of each of the plurality of display signal lines DSL. In this case, the plurality of compensation lines CL and the plurality of display signal lines DSL may be arranged within the same metal layer and may be the same number. In this specification, the compensation lines and the display signal lines may have the same length. In this case, the line width of each of the compensation lines and the display signal lines may have the same meaning as the area of each of the compensation lines and the display signal lines.

As another example, each of the plurality of compensation lines CL may have a different line width than each of the plurality of display signal lines DSL. In this case, the plurality of compensation lines CL and the plurality of display signal lines DSL may be arranged in different metal layers or may have different numbers. Furthermore, in this case, as an example, each of the plurality of compensation lines CL may have a line width smaller than each of the plurality of display signal lines DSL. In this case, as shown in FIG. 8, the plurality of compensation lines CL may be positioned closer to the common electrode CE than the plurality of display signal lines DSL. Accordingly, the first capacitor Cdc and the third capacitor Ccc may be identical.

As another example, within a specific area, the sum of the line widths of each of the plurality of compensation lines CL may correspond to the sum of the line widths of each of the plurality of display signal lines DSL.

As another example, in a case that the plurality of compensation lines CL positioned closer to the common electrode CE than the plurality of display signal lines DSL, the sum of the line widths of each of the plurality of compensation lines CL may be smaller than the sum of the line widths of each of the plurality of display signal lines DSL.

The above-mentioned specific area may be a unit area in which a first capacitor Cdc between a plurality of display signal lines DSL and a common electrode CE and a third capacitor Ccc between a plurality of compensation lines CL and a common electrode CE are formed in the same manner.

For example, the specific area may be a unit area including the same number of display signal lines DSL and compensation lines CL. In this case, the line width of each display signal line DSL and the line width of each compensation line CL may be the same. As another example, the specific area may be a unit area in which the first capacitor Cdc and the third capacitor Ccc are formed in the same manner, even if the number of the plurality of compensation lines CL and the number of the plurality of display signal lines DSL are different. In this case, the line width of each display signal line DSL and the line width of each compensation line CL may be different. As another example, the specific area may be a unit area including one or more pixels. As another example, the specific area may be an area in which two or more compensation lines CL are electrically connected and grouped into one group.

Hereinafter, referring to FIG. 9, it will be described the principle (i.e., noise compensation principle) by which noise is not generated or eliminated at the common electrode CE by a noise compensation structure including a compensation pattern CPT.

In the display device driven using the noise compensation structure, if a display signal VDS is applied to the display signal line DSL and a compensation signal VCOMP is applied to the compensation pattern CPT, the compensation signal VCOMP may have a voltage fluctuation amount ΔVc corresponding to a voltage fluctuation amount ΔVd of the display signal VDS, and the compensation signal VCOMP and the display signal VDS may have an antiphase relationship.

Since the compensation signal VCOMP and the display signal VDS have an antiphase relationship, when the voltage of the display signal line DSL increases, the voltage of the compensation pattern CPT may decrease, and when the voltage of the display signal line DSL decreases, the voltage of the compensation pattern CPT may increase.

According to noise compensation driving, since the compensation signal VCOMP and the display signal VDS have an antiphase relationship, a noise component Vcc generated at the common electrode CE due to voltage fluctuations of the compensation signal VCOMP may have an antiphase relationship with a noise component Vdc generated at the common electrode CE due to voltage fluctuations of the display signal VDS.

Therefore, the noise component Vcc generated at the common electrode CE due to voltage fluctuations of the compensation signal VCOMP and the noise component Vdc generated at the common electrode CE due to voltage fluctuations of the display signal VDS may cancel each other out. Accordingly, a voltage VCE at the common electrode CE can stably maintain the first common voltage VSS, which is a constant voltage.

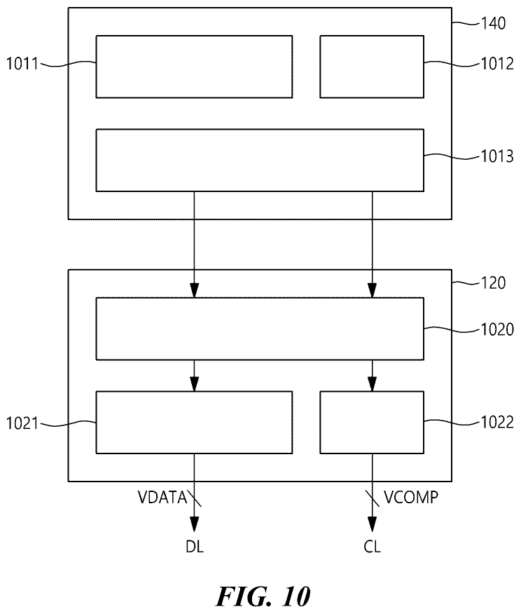

FIG. 10 illustrates a driving system for noise compensation of a display device 100 according to embodiments of the present disclosure. Hereinafter, it is assumed that the display signal line DSL is a data line DL.

Referring to FIG. 10, a driving system for noise compensation of a display device 100 according to embodiments of the present disclosure may include a controller 140 including a line memory 1011, an operation unit 1012, and a data supply unit 1013, and a driving circuit including a data receiving unit 1020, a source block 1021, and a compensation block 1022. For example, the driving circuit may be a data driving circuit 120.

For example, the controller 140 may output image data corresponding to a plurality of display signal lines DSL and output compensation signal data that varies depending on the image data, and the data driving circuit 120 may output data signals, which are display signals, based on the image data, and output a compensation signal based on the compensation signal data.

The line memory 1011 may store data corresponding to sub-pixels included in each of a plurality of sub-pixel lines.

The operation unit 1012 may refer to the data stored in the line memory 1011, may compare data (e.g., image data) corresponding to sub-pixels included in a sub-pixel line to be currently driven (e.g., sub-pixels connected to a plurality of data lines) with data (e.g., image data) corresponding to sub-pixels included in a previously driven sub-pixel line (e.g., sub-pixels connected to a plurality of data lines), may calculate a data variation amount (i.e., a digital value corresponding to a voltage fluctuation amount of a data signal) corresponding to each of the plurality of data lines, and may determine at least one compensation signal data (i.e., a digital value of a compensation signal VCOMP) based on the calculated data variation amount.

The data supply unit 1013 may supply at least one compensation signal data to the data driving circuit 120, along with data corresponding to sub-pixels included in the sub-pixel line to be currently driven (e.g., sub-pixels connected to a plurality of data lines).

The data receiving unit 1020 may receive data (i.e., image data) required for the current driving and at least one compensation signal data from the data supply unit 1013 of the controller 140.

The source block 1021 may convert the data (e.g., image data) required for the current driving into data signals VDATA in the form of analog voltages, and output the data signals VDATA to a plurality of data lines DL.

The compensation block 1022 may convert at least one compensation signal data from the data supply unit 1013 of the controller 140 into a compensation signal VCOMP in the form of an analog voltage, and output the compensation signal VCOMP to at least one compensation line CL included in the compensation pattern CPT.

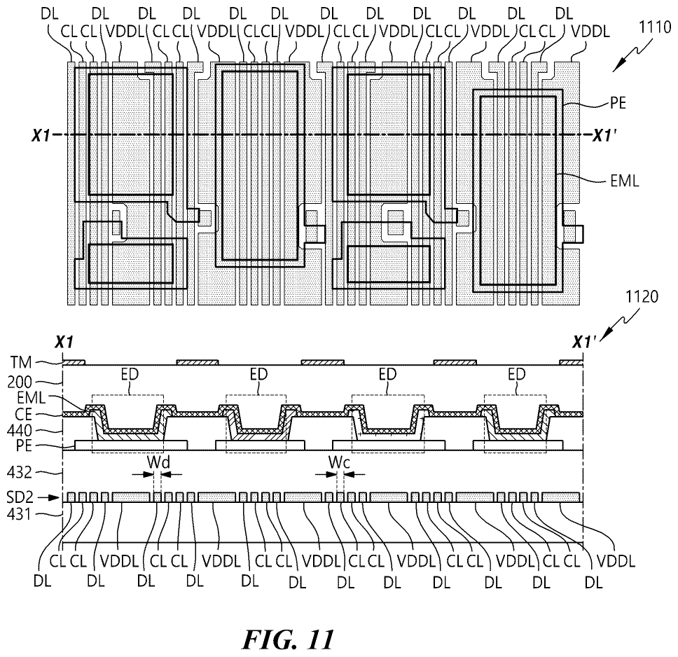

FIGS. 11 to 14 are plan views 1110, 1210, 1310, and 1410, and cross-sectional views 1120, 1220, 1320, and 1420 of a display panel 110 including a noise compensation structure according to embodiments of the present disclosure. Hereinafter, for convenience of explanation, it will be described a case in which the display signal VDS and the display signal line DSL are referred to as a data signal VDATA and a data line DL, respectively.

Referring to FIGS. 11 to 14, the cross-sectional views 1120, 1220, 1320, and 1420 are cross-sectional views taken along the cutting lines X1-X1′, X2-X2′, X3-X3′, and X4-X4′ in the plan views 1110, 1210, 1310, and 1410, respectively.

Referring to FIGS. 11 to 14, the display panel 110 may include data lines DL and display power lines VDDL. For example, the display power lines VDDL may be second common voltage lines VDDL corresponding to high-potential voltage lines. For example, two data lines DL may be arranged between two display power lines VDDL.

The display panel 110 may include a light emitting device ED for each sub-pixel SP. The light emitting device ED may be composed of a pixel electrode PE, an emission layer EML, and a common electrode CE. For example, the display panel 110 may have a top emission structure.

The data lines DL and the display power lines VDDL may be disposed on a first planarization layer 431. For example, the data lines DL and the display power lines VDDL may be disposed within a second source-drain metal layer SD2 on the first planarization layer 431.

A second planarization layer 432 may be disposed on the data lines DL and the display power lines VDDL.

The light emitting devices ED may be formed on the second planarization layer 432. A pixel electrode PE may be disposed on the second planarization layer 432, and a bank 440 may be disposed on the pixel electrode PE, and may have an opening exposing a portion of each pixel electrode PE. Each emission layer EML may be formed on a portion of the pixel electrode PE exposed by the opening of the bank 440, and a common electrode CE may be disposed commonly on the emission layers EML.

An encapsulation layer 200 may be disposed on the common electrode CE, and a touch metal TM included in the touch sensor layer 210 may be disposed on the encapsulation layer 200. The touch metal TM may overlap with the bank 440.

The display power line VDDL may be disposed within a metal layer (e.g., a second source-drain metal layer SD2) in which a plurality of data lines DL, which are one type of a plurality of display signal lines DSL, are disposed (formed/included), and may be supplied with a constant voltage (e.g., a second common voltage VDD) within a predefined range.

At least a portion of at least one of the plurality of compensation lines CL may overlap with the display power line VDDL and at least one of the plurality of display signal lines DSL.

Referring to FIGS. 11 to 14, the plurality of compensation lines CL included in the compensation pattern CPT may be disposed parallel to the plurality of display signal lines DSL.

Referring to FIG. 11, the plurality of compensation lines CL may be disposed one for each data line DL corresponding to one display signal line DSL. In this case, a line width Wc of the compensation line CL may be the same as a line width Wd of the data line DL, which is the display signal line DSL, or may be substantially the same within a tolerance range.

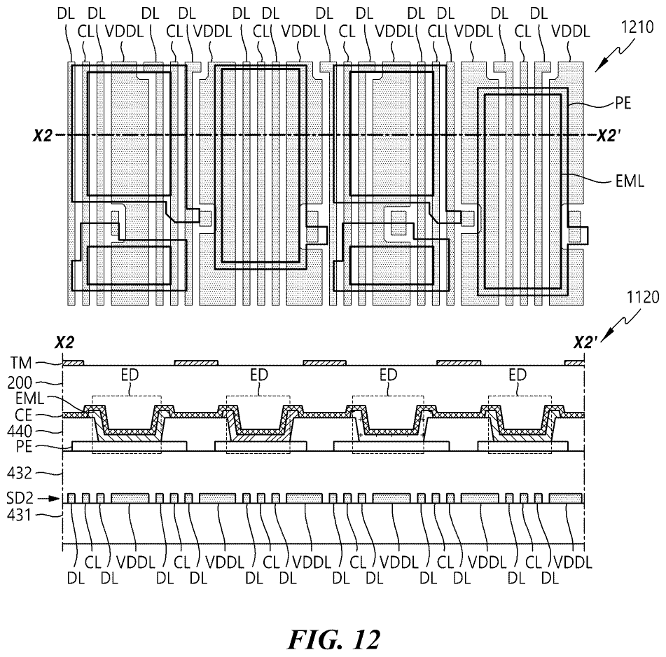

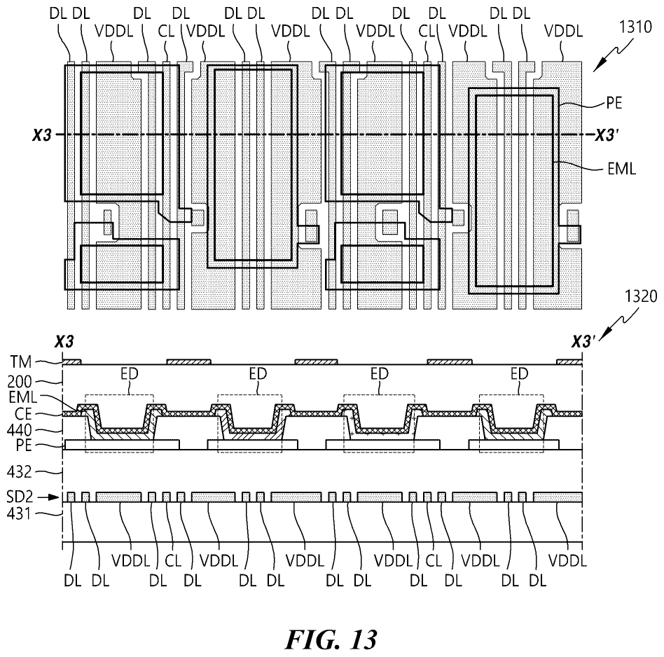

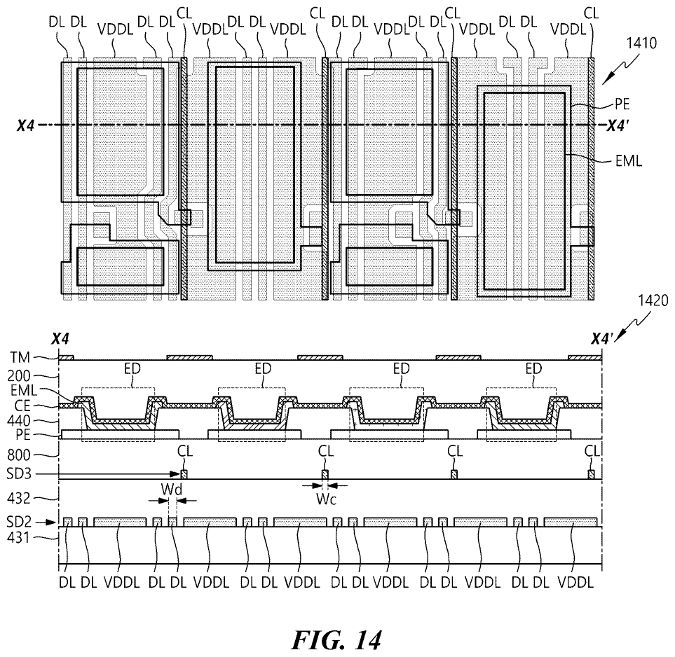

Referring to FIGS. 12 to 14, a plurality of compensation lines CL may be arranged for each of two or more data lines DL corresponding to two or more display signal lines DSL. For example, as shown in FIG. 12, a plurality of compensation lines CL may be arranged one for each of two data lines DL corresponding to two display signal lines DSL. As shown in FIG. 13, a plurality of compensation lines CL may be arranged one for each of six data lines DL corresponding to six display signal lines DSL. As shown in FIG. 14, a plurality of compensation lines CL may be arranged one for each of two to four data lines DL corresponding to two to four display signal lines DSL.

Referring to FIGS. 11 to 13, the plurality of compensation lines CL may be arranged within the same metal layer (e.g., a second source-drain metal layer SD2 made of a second source-drain metal) as the plurality of data lines DL corresponding to the plurality of display signal lines DSL.

Referring to FIG. 14, the plurality of compensation lines CL may be arranged within a metal layer (e.g., a third source-drain metal layer SD3 made of a third source-drain metal) different from a metal layer (e.g., a second source-drain metal layer SD2) in which the plurality of data lines DL corresponding to the plurality of display signal lines DSL are arranged (formed/included).

In this case, the plurality of compensation lines CL may be arranged on the second planarization layer 432, and the third planarization layer 800 may be arranged on the plurality of compensation lines CL. The light emitting devices ED may be disposed on the third planarization layer 800.

As illustrated in FIG. 14, if the compensation line CL is arranged closer to the common electrode CE than the data line DL, a distance between the compensation line CL and the common electrode CE may become shorter than a distance between the data line DL and the common electrode CE.

Accordingly, the value (e.g., capacitance) of the third capacitor Ccc between the compensation line CL and the common electrode CE may be smaller than the value of the first capacitor Cdc between the data line DL and the common electrode CE. In this way, noise generated at the common electrode CE due to voltage fluctuations of the compensation line CL and noise generated at the common electrode CE due to voltage fluctuations of the data line DL may be slightly canceled out, but the degree of canceling may be small.

In the display device 100 according to embodiments of the present disclosure, the line width Wc of the compensation line CL may be designed to be smaller than the line width Wd of the data line DL. Accordingly, the values of the first capacitor Cdc and the third capacitor Ccc may be equal to or as similar as possible. As a result, noise generated at the common electrode CE due to voltage fluctuations of the compensation line CL and noise generated at the common electrode CE due to voltage fluctuations of the data line DL may be completely canceled out.

In the display device 100 according to embodiments of the present disclosure, the voltage fluctuation value ΔVc of the compensation signal VCOMP may be set to be smaller than the voltage fluctuation value ΔVd of the data signal VDATA. Accordingly, the values of the first capacitor Cdc and the third capacitor Ccc may be equal to or as similar as possible. As a result, noise generated at the common electrode CE due to voltage fluctuations of the compensation line CL and noise generated at the common electrode CE due to voltage fluctuations of the data line DL can be completely canceled out.

Meanwhile, the display device 100 according to embodiments of the present disclosure may drive a plurality of compensation lines CL included in a compensation pattern CPT using either an individual driving method or a group driving method.

According to the individual driving method, a compensation signal VCOMP may be individually applied to the plurality of compensation lines CL included in the compensation pattern CPT. According to the group driving method, the plurality of compensation lines CL may be grouped into two or more groups, and a compensation signal VCOMP may be applied to each group.

The display device 100 according to embodiments of the present disclosure described above is briefly summarized as follows. A display device 100 according to embodiments of the present disclosure may include a touch sensor layer 210 including a plurality of touch metals TM, a common electrode CE coupled capacitively with the touch sensor layer 210 and having a constant voltage (e.g., a first common voltage VSS) within a predefined range during a first driving period, a display signal line DSL coupled capacitively with the common electrode CE and having a voltage fluctuation over time in a second period (e.g., a second voltage fluctuation period) during the first driving period, and a compensation pattern CPT coupled capacitively with the common electrode CE and electrically isolated from the display signal line DSL, but having a voltage fluctuation synchronized with a voltage fluctuation timing of the display signal line DSL during the first driving period.

If the voltage of the display signal line DSL increases or rises, the voltage of the compensation pattern CPT may decrease or fall, and if the voltage of the display signal line DSL decreases, the voltage of the compensation pattern CPT may increase.

A compensation signal VCOMP may be applied to the compensation pattern CPT. The compensation signal VCOMP may fluctuate over time in synchronization with the voltage fluctuation timing of the display signal VDS applied to the display signal line DSL. The compensation signal VCOMP may have an antiphase relationship with the display signal VDS.

During the first driving period, display driving and touch driving may be performed simultaneously. For example, the first driving period may be an active period among an active period and a blank period defined by a vertical synchronization signal.

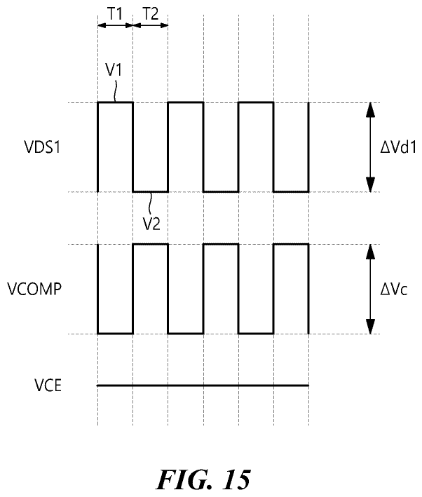

FIGS. 15 to 17 illustrate a data signal and a compensation signal VCOMP according to embodiments of the present disclosure. Hereinafter, reference will be made to FIGS. 1 to 14 together.

The plurality of compensation lines CL may be arranged one for each display signal line DSL. In this case, as illustrated in FIG. 15, the compensation signal VCOMP may have a voltage fluctuation value ΔVc corresponding to (or same as) a first voltage fluctuation value ΔVd1 of the first display signal VDATA1 supplied to the first display signal line DSL adjacent to the compensation pattern CPT among the plurality of display signal lines DSL. Accordingly, noise at the common electrode CE may be reduced or eliminated, so that the voltage VCE of the common electrode CE may have a constant voltage value.

Referring to FIG. 15, during a first period T1, a display signal VDS1 supplied to a first display signal line DSL may have a first voltage V1, and during a second period T2 following the first period T1, a display signal VDS1 supplied to the first display signal line DSL may have a second voltage V2 different from the first voltage V1.

The voltage difference ΔVc between the compensation signal VCOMP during the first period T1 and the compensation signal VCOMP during the second period T2 may vary depending on a voltage fluctuation value ΔVd1, which is a voltage difference between the first voltage V1 and the second voltage V2.

Referring to FIG. 15 and FIG. 10 together, the controller 140 may calculate compensation signal data based on first data of a first period T1 corresponding to a first display signal line DSL and second data of a second period T2 corresponding to the first display signal line DSL, and output the second data and the compensation signal data.

The data driving circuit 120 may convert the second data into a first display signal VDATA1 having a second voltage V2, convert the compensation signal data into a compensation signal VCOMP corresponding to an analog voltage, and output the first display signal VDATA1 having the second voltage V2 to the first display signal line DSL and output the compensation signal VCOMP to a compensation pattern CPT during the second period T2.

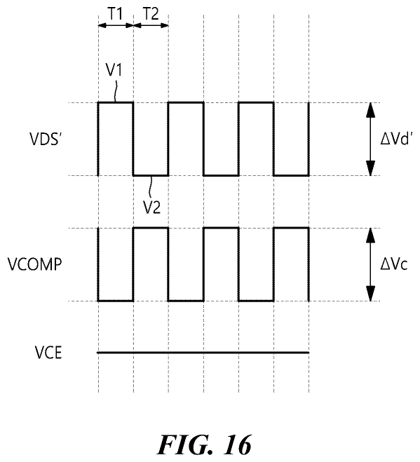

The plurality of compensation lines CL may be arranged one for each of two or more display signal lines DSL. In this case, as illustrated in FIG. 16, the compensation signal VCOMP may have a voltage fluctuation value ΔVc corresponding to (or same as) an average value ΔVd′ of the voltage fluctuation values of two or more display signals VDS' supplied to two or more display signal lines DSL adjacent to the compensation pattern CPT among the plurality of display signal lines DSL. Accordingly, it is possible to reduce or eliminate a noise at the common electrode CE, so that the voltage VCE of the common electrode CE may have a constant voltage value.

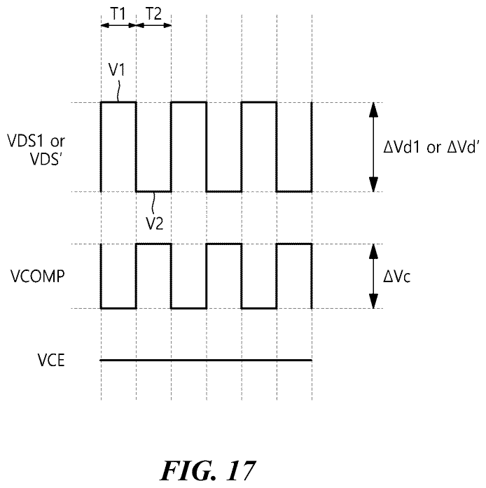

For example, in the case that the compensation line CL is arranged closer to the common electrode CE than the display signal line DSL, as illustrated in FIG. 17, the voltage fluctuation value ΔVc of the compensation signal VCOMP may be smaller than the first voltage fluctuation value ΔVd1 of a first display signal VDS1 supplied to a first display signal line DSL that is closest to the compensation pattern CPT among the plurality of display signal lines DSL.

For another example, if the compensation line CL is arranged closer to the common electrode CE than the display signal line DSL, as illustrated in FIG. 17, the voltage fluctuation value ΔVc of the compensation signal VCOMP may be smaller than the average value ΔVd′ of the voltage fluctuation values of two or more display signals VDS' supplied to two or more display signal lines DSL that are adjacent to the compensation pattern CPT among the plurality of display signal lines DSL.

Accordingly, even if the compensation line CL is positioned closer to the common electrode CE than the display signal line DSL, it is possible to normally reduce or eliminate the noise at the common electrode CE.

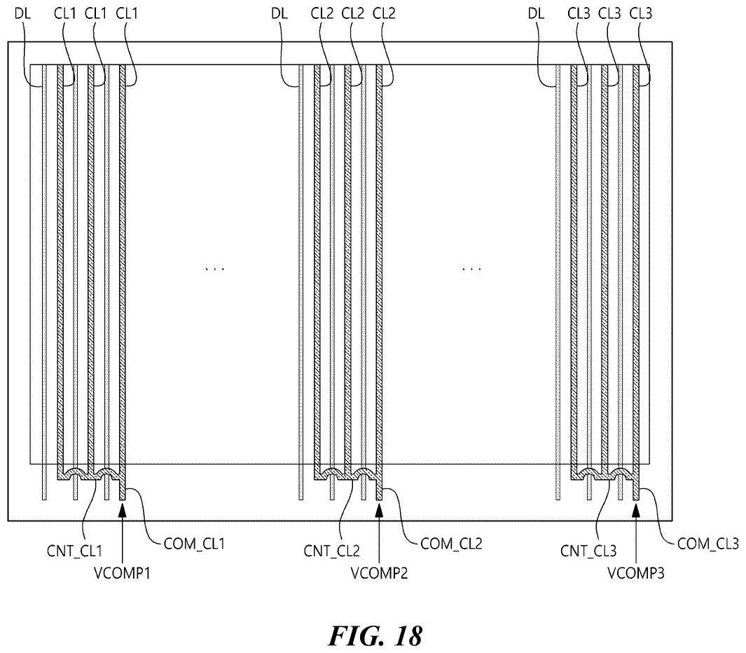

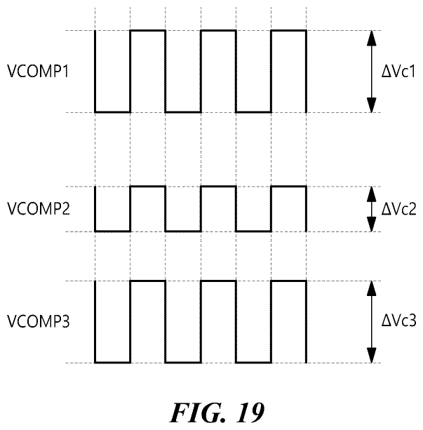

FIG. 18 illustrates a group driving structure for a compensation pattern CPT according to embodiments of the present disclosure, and FIG. 19 illustrates first to third compensation signals VCOMP applied to first to third groups during group driving of the compensation pattern CPT according to embodiments of the present disclosure.

Referring to FIG. 18, if a plurality of compensation lines CL are driven according to a group driving method, the plurality of compensation lines CL may be grouped into two or more groups, and a compensation signal VCOMP may be applied to each group.

For example, the plurality of compensation lines CL may include two or more first compensation lines CL1 grouped into a first group, two or more second compensation lines CL2 grouped into a second group, and two or more third compensation lines CL3 grouped into a third group.

One first compensation signal VCOMP1 may be supplied to two or more first compensation lines CL1, one second compensation signal VCOMP2 may be supplied to two or more second compensation lines CL2, and one third compensation signal VCOMP3 may be supplied to two or more third compensation lines CL3.

For example, the first voltage fluctuation value ΔVc1 of the first compensation signal VCOMP1, the second voltage fluctuation value ΔVc2 of the second compensation signal VCOMP2, and the third voltage fluctuation value ΔVc3 of the third compensation signal VCOMP3 may all be the same.

As another example, as illustrated in FIG. 19, at least one of the first voltage fluctuation value ΔVc1 of the first compensation signal VCOMP1, the second voltage fluctuation value ΔVc2 of the second compensation signal VCOMP2, and the third voltage fluctuation value ΔVc3 of the third compensation signal VCOMP3 may be different from the others.

The compensation pattern CPT may include a plurality of compensation lines CL, a first compensation connection line CNT_CL1 electrically connecting two or more first compensation lines CL1 among the plurality of compensation lines CL, a second compensation connection line CNT_CL2 electrically connecting two or more second compensation lines CL2 among the plurality of compensation lines CL, and a third compensation connection line CNT_CL3 electrically connecting two or more third compensation lines CL3 among the plurality of compensation lines CL.

A first compensation signal VCOMP1 input to a first input terminal COM_CL1 may be supplied to two or more first compensation lines CL1 through the first compensation connection line CNT_CL1.

A second compensation signal VCOMP2 input to a second input terminal COM_CL2 may be supplied to two or more second compensation lines CL2 through the second compensation connection line CNT_CL2.

A third compensation signal VCOMP3 input to a third input terminal COM_CL3 may be supplied to two or more third compensation lines CL3 through the third compensation connection line CNT_CL3.

A voltage fluctuation period of the first compensation signal VCOMP1 may correspond to a voltage fluctuation period of display signals VDS supplied to two or more display signal lines DSL adjacent to two or more first compensation lines CL1 among a plurality of display signal lines DSL. The first voltage fluctuation value ΔVc1 of the first compensation signal VCOMP1 may correspond to an average value of the voltage fluctuation values of the display signals VDS supplied to two or more display signal lines DSL adjacent to two or more first compensation lines CL1.

A voltage fluctuation period of the second compensation signal VCOMP2 may correspond to a voltage fluctuation period of the display signals VDS supplied to two or more display signal lines DSL adjacent to two or more second compensation lines CL2 among the plurality of display signal lines DSL. The second voltage fluctuation value ΔVc2 of the second compensation signal VCOMP2 may correspond to an average value of the voltage fluctuation values of the display signals VDS supplied to two or more display signal lines DSL adjacent to two or more second compensation lines CL2.

A voltage fluctuation period of the third compensation signal VCOMP3 may correspond to the voltage fluctuation period of the display signals VDS supplied to two or more display signal lines DSL adjacent to two or more third compensation lines CL3 among the plurality of display signal lines DSL. The third voltage fluctuation value ΔVc3 of the third compensation signal VCOMP3 may correspond to the average value of the voltage fluctuation values of the display signals VDS supplied to two or more display signal lines DSL adjacent to two or more third compensation lines CL3.

The second compensation signal VCOMP2 may be in phase with the first compensation signal VCOMP1, and the third compensation signal VCOMP3 may be in phase with the second compensation signal VCOMP2. That is, the first to third compensation signals VCOMP1 to VCOMP3 may all have in-phase relationship with each other.

For example, the second compensation signal VCOMP2 may have a second voltage fluctuation value ΔVc2 that is the same as the first voltage fluctuation value ΔVc1 of the first compensation signal VCOMP1. As another example, the second compensation signal VCOMP2 may have a second voltage fluctuation value ΔVc2 different from the first voltage fluctuation value ΔVc1 of the first compensation signal VCOMP1.

For example, the third compensation signal VCOMP3 may have a third voltage fluctuation value ΔVc2 that is the same as the first voltage fluctuation value ΔVc1 of the first compensation signal VCOMP1. As another example, the third compensation signal VCOMP3 may have a third voltage fluctuation value ΔVc3 that is different from the first voltage fluctuation value ΔVc1 of the first compensation signal VCOMP1.

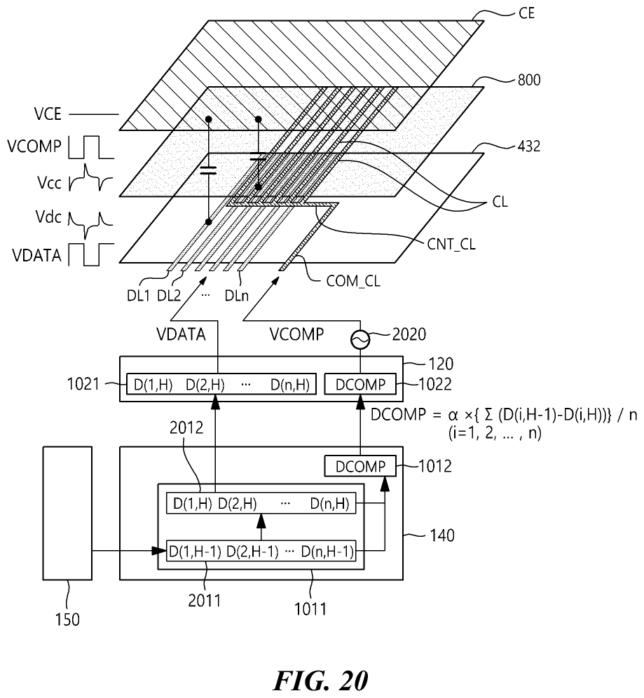

FIG. 20 illustrates a driving system for group driving of a compensation pattern CPT according to embodiments of the present disclosure. In the following description, FIGS. 10, 14, and 18 will also be referred to.

Referring to FIG. 20, a second planarization layer 432 may be disposed on n data lines DL1 to DLn, and a plurality of compensation lines CL grouped into one may be disposed on the second planarization layer 432. In addition, a third planarization layer 800 may be disposed on the plurality of compensation lines CL grouped into one, and a common electrode CE may be disposed on the third planarization layer 800.

The plurality of compensation lines CL grouped into one may be electrically connected by a single compensation connection line CNT_CL. The n data lines DL1 to DLn may be data lines adjacent to the plurality of compensation lines CL grouped into one.

The data driving circuit 120 may supply data signals VDATA to n data lines DL1 to DLn, and supply a compensation signal VCOMP to a compensation connection line CNT_CL through an input terminal COM_CL. Here, the compensation signal VCOMP may have an antiphase relationship with the data signals VDATA. The voltage fluctuation value of the compensation signal VCOMP may correspond to the average value of the voltage fluctuation values of the data signals VDATA.

Input image data supplied from the host system 150 may be stored in the line memory 1011 of the image controller 140.

The line memory 1011 may include a first memory space 2011 that stores previous image data D(1,H−1), D(2,H−1), . . . , and D(n,H−1) used when driving a first sub-pixel line (H−1) during the previous driving period, and a second memory space 2012 that stores current image data D(1,H), D(2,H), . . . , and D(n,H) that is required to be used to drive a second sub-pixel line (H) during the current driving period.

Previous image data D(1,H−1), D(2,H−1), . . . , and D(n,H−1) may correspond to n data lines (DL1 to DLn), and current image data D(1,H), D(2,H), . . . , and D(n,H) may correspond to n data lines DL1 to DLn.

The operation unit 1012 may multiply the average value (Σ(D(i,H−1)−D(i,H))/n) of the differences (D(i,H−1)−D(i,H), i=1, 2, . . . , n) between the previous image data D(1, H−1), D(2, H−1), . . . , and D(n, H−1) and the current image data D(1, H), D(2, H), . . . , and D(n, H) of the second memory space 2012 for each of n data lines DL1 to DLn by a predefined constant α, thereby producing compensation signal data DCOMP. Here, ‘I’ is a sequence of data lines, and ‘n’ is the number of data lines corresponding to one group for compensation driving.

The source block 1021 may receive current image data D(1, H), D(2, H), . . . , and D(n, H) from the controller 140, convert the current image data D(1, H), D(2, H), . . . , and D(n, H) into data signals VDATA in the form of analog voltages, and output the data signals VDATA to n data lines DL1 to DLn.

The compensation block 1022 may convert the compensation signal data DCOMP produced from the operation unit 1012 into a compensation signal VCOMP in the form of an analog voltage, and output the compensation signal VCOMP to the compensation connection line CNT_CL through the input terminal COM_CL. The compensation block 1022 may further include an output unit 2020 that converts and outputs the characteristics (e.g., voltage level, etc.) of the compensation signal VCOMP.

According to the group driving method, a noise component Vdc generated at the common electrode CE due to voltage fluctuations in the data signals VDATA and a noise component Vcc generated at the common electrode CE due to voltage fluctuations in the compensation signal VCOMP may be canceled out. Accordingly, even if the voltages of the data lines DL1 to DLn fluctuate, noise at the common electrode CE can be reduced or eliminated. As a result, it is possible to improve the display quality and touch sensing quality.

According to embodiments of the present disclosure, even if the voltage of at least one display signal line fluctuates during display driving, the common electrode may maintain a constant voltage through a noise compensation structure, thereby improving display quality.

According to embodiments of the present disclosure, even if the voltage of at least one display signal line fluctuates during display driving, the touch sensor may maintain a desired voltage state by a noise compensation structure, thereby improving touch sensing quality.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a plurality of display signal lines arranged on a substrate;
a common electrode arranged above the plurality of display signal lines and overlapping with the plurality of display signal lines; and
a compensation structure overlapping with the common electrode and receiving a compensation signal,
wherein the compensation signal has a voltage that fluctuates in synchronization with a voltage fluctuation timing of a display signal supplied to at least one display signal line among the plurality of display signal lines, and has an antiphase relationship with the display signal.

2. The display device of claim 1, further comprising:
an encapsulation layer disposed on the common electrode; and
a touch sensor layer disposed on the encapsulation layer, overlapping with the common electrode, and overlapping with at least a portion of the compensation structure.

3. The display device of claim 1, wherein the compensation structure is disposed within a same metal layer as the plurality of display signal lines.

4. The display device of claim 1, wherein the compensation structure includes a plurality of compensation lines,
wherein a line width of each of the plurality of compensation lines is equal to a line width of each of the plurality of display signal lines, or a sum of line widths of each of the plurality of compensation lines corresponds to a sum of line widths of each of the plurality of display signal lines.

5. The display device of claim 1, wherein the compensation structure is disposed between a metal layer in which the plurality of display signal lines are arranged and the common electrode.

6. The display device of claim 1, wherein the compensation structure includes a plurality of compensation lines, and
wherein each of the plurality of compensation lines has a line width smaller than a line width of each of the plurality of display signal lines, or a sum of line widths of each of the plurality of compensation lines is smaller than a sum of line widths of each of the plurality of display signal lines.

7. The display device of claim 1, wherein the compensation structure includes a plurality of compensation lines arranged in parallel with the plurality of display signal lines, and
wherein the plurality of compensation lines are arranged one for each display signal line.

8. The display device of claim 1, wherein the compensation structure includes a plurality of compensation lines arranged in parallel with the plurality of display signal lines, and
wherein a number of the plurality of compensation lines is different from a number of the plurality of display signal lines.

9. The display device of claim 1, further comprising a display power line arranged within a metal layer in which the plurality of display signal lines are arranged, and to which a constant voltage is applied within a predefined range,
wherein the compensation structure includes a plurality of compensation lines, and at least a portion of at least one of the plurality of compensation lines overlaps with the display power line and at least one of the plurality of display signal lines.

10. The display device of claim 1, wherein the compensation signal has a voltage fluctuation value corresponding to a first voltage fluctuation value of a first display signal supplied to a first display signal line adjacent to the compensation structure among the plurality of display signal lines.

11. The display device of claim 1, wherein the compensation signal has a voltage fluctuation value corresponding to an average value of voltage fluctuation values of two or more display signals supplied to two or more display signal lines adjacent to the compensation structure among the plurality of display signal lines.

12. The display device of claim 1, wherein a voltage fluctuation value of the compensation signal is less than a first voltage fluctuation value of a first display signal supplied to a first display signal line closest to the compensation structure among the plurality of display signal lines, or
wherein a voltage fluctuation value of the compensation signal is less than an average value of voltage fluctuation values of two or more display signals supplied to two or more display signal lines adjacent to the compensation structure among the plurality of display signal lines.

13. The display device of claim 1, further comprising:
a controller configured to output image data corresponding to the plurality of display signal lines and configured to output compensation signal data that varies according to the image data; and
a driving circuit configured to output data signals, which are display signals, based on the image data, and configured to output the compensation signal based on the compensation signal data.

14. The display device of claim 1, wherein the compensation structure includes a plurality of compensation lines, and
wherein a compensation signal is applied individually to the plurality of compensation lines, or the plurality of compensation lines are grouped into two or more groups and the compensation signal is applied to each group.

15. The display device of claim 14, wherein the plurality of compensation lines include two or more first compensation lines grouped into a first group and two or more second compensation lines grouped into a second group,
wherein one first compensation signal is supplied to the two or more first compensation lines,
wherein one second compensation signal is supplied to the two or more second compensation lines, and
wherein the first compensation signal and the second compensation signal are in phase, and a voltage fluctuation value of the first compensation signal and a voltage fluctuation value of the second compensation signal are different.

16. A display device comprising:
a touch sensor layer supplied with a voltage having a first voltage fluctuation over time during a first driving period;
a common electrode capacitively coupled to the touch sensor layer and supplied with a constant voltage during the first driving period;
a display signal line capacitively coupled to the common electrode and supplied with a voltage having a second voltage fluctuation over time during the first driving period; and
a metal pattern capacitively coupled to the common electrode and supplied with a voltage having a third voltage fluctuation synchronized with the second voltage fluctuation of the display signal line during the first driving period,
wherein a voltage of the metal pattern decreases in response to an increase in a voltage of the display signal line, and
wherein the voltage of the metal pattern increases in response to a decrease in the voltage of the display signal line.

17. The display device of claim 16, wherein a compensation signal having a voltage that fluctuates in synchronization with a voltage fluctuation of a display signal applied to the display signal line is applied to the metal pattern, and
wherein the compensation signal has an antiphase relationship with the display signal.

18. The display device of claim 16, wherein the metal pattern is disposed within a same metal layer as the display signal line.

19. The display device of claim 16, wherein the metal pattern is disposed within a metal layer different from a metal layer in which the display signal line is disposed.

20. The display device of claim 16, wherein a voltage fluctuation value of the metal pattern is smaller than a voltage fluctuation value of the display signal line.
